(19) United States
(12) Patent Application Publication
(10) Pub. No.: US 2008/0087926 A1
(43) Pub. Date: Apr. 17, 2008

(54) FERROELECTRIC RANDOM ACCESS MEMORY AND METHODS OF FABRICATING THE SAME

(75) Inventors: Jung-Hoon Park, Seocho-gu (KR); Heung-Jin Joo, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/853,039

(22) Filed: Sep. 11, 2007

(30) Foreign Application Priority Data
Sep. 11, 2006 (KR) 2006-87664

(51) Int. Cl. H01L 21/8242; H01L 27/108

(52) U.S. Cl. 257/295; 438/3; 257/E21.647; 257/E27.084

(57) ABSTRACT

A method of forming a ferroelectric random access memory includes sequentially forming a conductive pattern, an etch-stop layer, a ferroelectric capacitor and an interlayer dielectric on a semiconductor substrate, which includes a first region and a second region. The ferroelectric capacitor is formed on the first region and the conductive pattern is formed on the second region. The interlayer dielectric is patterned to simultaneously form a first opening to expose a top surface of the ferroelectric capacitor and a second opening to expose a top surface of the etch-stop layer. The patterned interlayer dielectric is annealed in an ambient atmosphere, including oxygen atoms. The etch-stop layer exposed through the second opening is etched to expose a top surface of the conductive pattern. First and second top plugs are formed to connect to the ferroelectric capacitor and the conductive pattern through the first and second openings, respectively.

### CROSS-REFERENCE TO RELATED APPLICATION

A claim of priority is made to Korean Patent Application No. 10-2006-0087664, filed on Sep. 11, 2006, the subject matter of which is hereby incorporated by reference.

### BACKGROUND

1. Field of the Invention

The present invention relates to semiconductor devices and methods of fabricating the same. More specifically, the present invention is directed to a ferroelectric random access memory and methods of fabricating the ferroelectric random access memory.

2. Description of the Related Art

In recent years, limitations of dynamic random access memories (DRAMs) related to volatility have led to research of a ferroelectric random access memory (FeRAM) having a ferroelectric thin film. The ferroelectric thin film exhibits hysterisis characteristics, which result from remnant polarization characteristics of ferroelectric materials. The FeRAM uses the hysterisis characteristics to retain its stored data irrespective of power supply interruption. Further, the operating speed of the FeRAM is as high as that of a DRAM. Accordingly, FeRAMs are becoming increasingly attractive as next-generation memory devices.

According to a conventional method of forming the FeRAM, electric charges may be accumulated in a top electrode of a ferroelectric capacitor, while forming a contact hole exposing the top electrode. Since the charge accumulation results in degradation of the remnant polarization characteristic, the conventional method further includes annealing the top electrode in ambient oxygen. However, conductive patterns constituting interconnection lines may be oxidized by the oxygen annealing. Because the oxidation of conductive patterns may result in breaking the patterns, the oxidation of the interconnections should be reduced.

FIG. 1 is a flowchart showing a conventional method applied to prevent oxidation of an interconnection. FIGS. 2A and 2B are cross-sectional views illustrating the conventional method.

Referring to FIG. 1 and FIG. 2A, transistors are formed on a semiconductor substrate 10, including a cell array region and a peripheral circuit region. Each of the transistors includes a gate electrode 20G, a source electrode 20S and a drain electrode 20D. Conductive patterns 50 are formed on the resultant structure where the transistors are formed (S10). The conductive patterns 50 are electrically connected to the electrodes 20G, 20S and 20D. As illustrated in FIG. 2A, plugs 32 may be formed between the conductive pattern 50 and source electrodes 20S, drain electrodes 20D or gate electrodes 20G, and between the conductive pattern 50 and studs 31, which may connect adjacent source or drain electrodes 20S/20D. First and second interlayer dielectrics 41 and 42 may be formed for electrical insulation and structural support between the plugs 32.

A third interlayer dielectric 43 is formed on the resultant structure where the conductive patterns 50 are formed. Ferroelectric capacitors 60 (using the ferroelectric layer as a dielectric layer of the capacitor) are formed on the third interlayer dielectric 43 (S12). A fourth interlayer dielectric 44 is formed on the resultant structure where the ferroelectric capacitors 60 are formed (S14). The fourth and third interlayer dielectrics 44 and 43 are patterned to define a first opening 71 partially exposing the top surface of the conductive patterns 50 (S16). According to the conventional method, the top surface of the ferroelectric capacitor 60 is not exposed at step S16.

First top plugs 81 are formed to fill the first openings 71 (S18). An oxygen-blocking layer 45 is formed on the resultant structure where the first top plugs 81 are formed (S20). The oxygen-blocking layer 45 and the fourth interlayer dielectric 44 are patterned to define a second opening 72 partially exposing the top surface of the ferroelectric capacitors 60 (S22). An annealing step 99 is performed in an ambient atmosphere, including oxygen atoms, for the resultant structure where the second opening 72 is formed (S24). Because the oxygen-blocking layer 45 covers the top surfaces of the first top plugs 81, as illustrated in FIG. 2A, the first top plugs 81 are not oxidized during the oxygen annealing 99.

Referring to FIG. 1 and FIG. 2B, the oxygen-blocking layer 45 is removed to expose the top surface of the first top plugs 81 (S26). Second top plugs 82 are formed in the second openings 72 to be connected to the top surface of the ferroelectric capacitors 60 (S28). A top interconnection 90 is formed to be connected to the first and second top plugs 81 and 82.

According to the conventional method, the first and second openings 71 and 72 are formed through different patterning steps. That is, at least two photolithography steps and at least two etching steps are required to form the first and second openings 71 and 72. Performing more processing steps increases the semiconductor fabricating cost. Accordingly, there is a need for fewer processing steps in FeRAM forming methods to reduce costs, while still preventing unwanted oxidation of interconnections.

### SUMMARY OF THE INVENTION

An aspect of the present invention provides a method of fabricating a ferroelectric random access memory. The method includes sequentially forming a conductive pattern, an etch-stop layer, a ferroelectric capacitor and an interlayer dielectric on a semiconductor substrate, which includes a first region and a second region. The ferroelectric capacitor is formed on the first region and the conductive pattern is formed on the second region. The interlayer dielectric is patterned to simultaneously form a first opening to expose a top surface of the ferroelectric capacitor and a second opening to expose a top surface of the etch-stop layer. The patterned interlayer dielectric, in which the first and second openings are formed, is annealed in an ambient atmosphere, including oxygen atoms. The etch-stop layer exposed through the second opening is etched to expose a top surface of the conductive pattern. A first top plug and a second top plug are simultaneously formed to be connected to the ferroelectric capacitor and the conductive pattern through the first and second openings, respectively.

The etch-stop layer may include an insulating material to prevent oxygen atoms from penetrating. The etch-stop layer may be formed using at least one of low pressure chemical vapor deposition silicon nitride (LP-CVD SiN), plasma enhanced chemical vapor deposition silicon nitride (PE-CVD SiN), chemical vapor deposition aluminum oxide (CVD Al2O3), and atomic layer deposition aluminum oxide (ALD Al2O3). The etch-stop layer may be formed to cover the entire surface of the semiconductor substrate during the annealing, preventing oxygen atoms from coming in contact with the conductive pattern.

Forming the conductive pattern and the etch-stop layer may include forming a bottom interlayer dielectric on the semiconductor substrate, where the bottom interlayer dielectric includes a groove region for defining the conductive pattern. A conductive layer is formed on the bottom interlayer dielectric to fill the groove region. The conductive layer is planarized to a top surface of the bottom interlayer dielectric to form the conductive pattern disposed in the groove region. The etch-stop layer is formed on a surface including the conductive pattern.

The etch-stop layer may be formed to cover only a top surface of the conductive pattern during the annealing, preventing oxygen atoms from coming in contact with the conductive pattern. Forming the conductive pattern and the etch-stop layer may include sequentially forming a conductive layer and a capping layer on the semiconductor substrate, and patterning the capping layer and the conductive layer to form the conductive pattern and the etch-stop layer, which is sequentially stacked on the conductive pattern. The etch-stop layer may be self-aligned with the conductive pattern.

The conductive pattern may include at least one of tungsten, aluminum and copper. Also, each of the first top plug and the second top plug may include at least one of tungsten, aluminum and copper, and the first top plug and the second top plug may be made of the same material.

Another aspect of the present invention provides a ferroelectric random access memory, including a conductive pattern and a ferroelectric capacitor located on a first region and a second region of a semiconductor substrate, respectively. An interlayer dielectric is located on the conductive pattern and the ferroelectric capacitor, the interlayer dielectric defining a first opening and a second opening formed in the first region and the second region, respectively. An insulative etch-stop layer is located between the conductive pattern and the interlayer dielectric. A first top plug and a second top plug are located in the first opening and the second opening, respectively. The insulative etch-stop layer includes at least one material having an etch selectivity with respect to the interlayer dielectric and having an oxygen-blocking property to prevent oxygen from penetrating into the conductive pattern. The first top plug is connected to a top surface of the ferroelectric capacitor and the second top plug is connected to a top surface of the conductive pattern through the etch-stop layer.

The first and second top plugs may include substantially the same material, and may be formed concurrently. The conductive pattern and each of the first and second top plugs may include at least one of tungsten, aluminum and copper.

The insulative etch-stop layer may include at least one of LP-CVD SiN, PE-CVD SiN, CVD Al2O3 and ALD Al2O3. Also, the insulative etch-stop layer may be self-aligned with the conductive pattern. The insulative etch-stop layer may extend across substantially the entire surface of the semiconductor substrate, except where the second top plug is formed.

### BRIEF DESCRIPTION OF THE DRAWINGS

The embodiments of the present invention will be described with reference to the attached drawings, in which:

FIG. 1 is a flowchart showing a conventional method of forming an FeRAM.

FIGS. 2A and 2B are cross-sectional views illustrating the conventional method of FIG. 1.

FIG. 3 is a flowchart showing a method of forming an FeRAM, according to an illustrative embodiment of the present invention.

FIGS. 4A through 4F are cross-sectional views illustrating the method of FIG. 3, according too an illustrative embodiment of the present invention.

FIG. 5 is a flowchart showing a method of forming an FeRAM, according to an illustrative embodiment of the present invention.

FIGS. 6A and 6B are cross-sectional views illustrating the method of FIG. 5, according to an illustrative embodiment of the present invention.

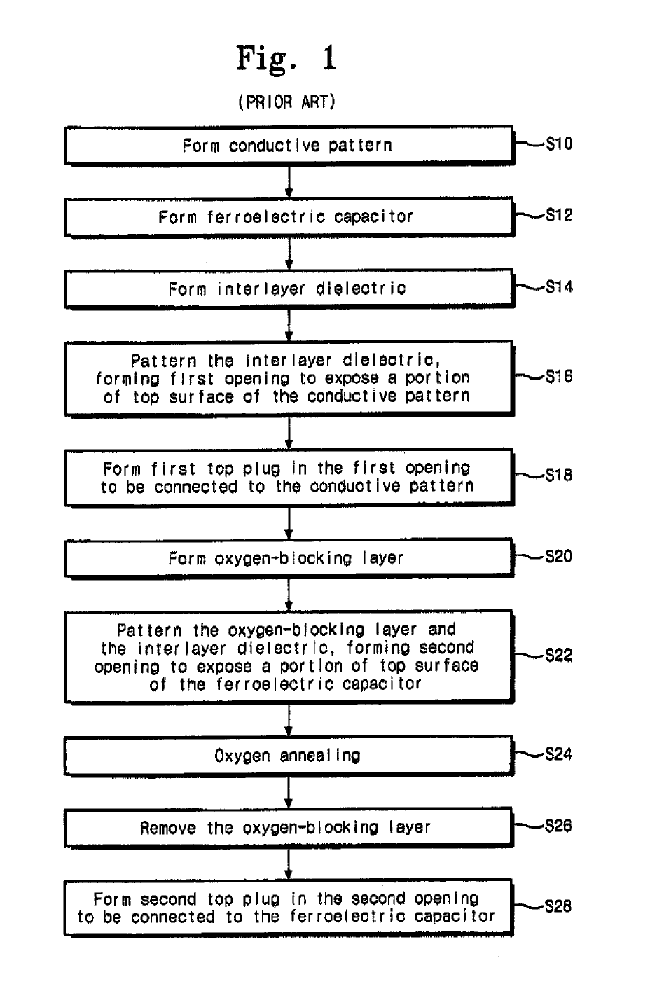

### DETAILED DESCRIPTION OF THE EMBODIMENTS

The present invention will now be described more fully with reference to the accompanying drawings, in which illustrative embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements. Also, in the drawings, the thicknesses of layers and regions are exaggerated for clarity. It is also understood that when a layer is referred to as being “on” another layer or substrate, it can be directly on the other layer or substrate, or intervening layers may also be present.

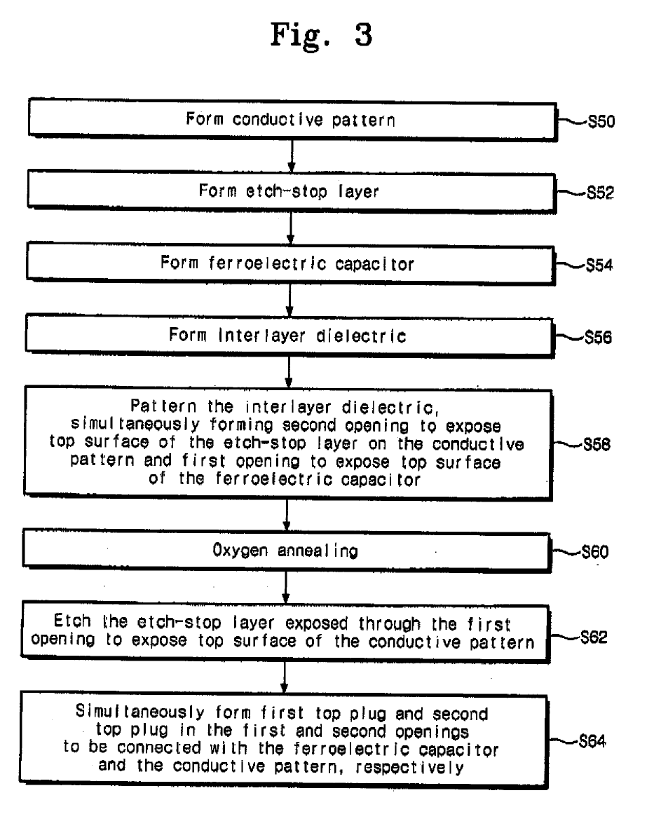

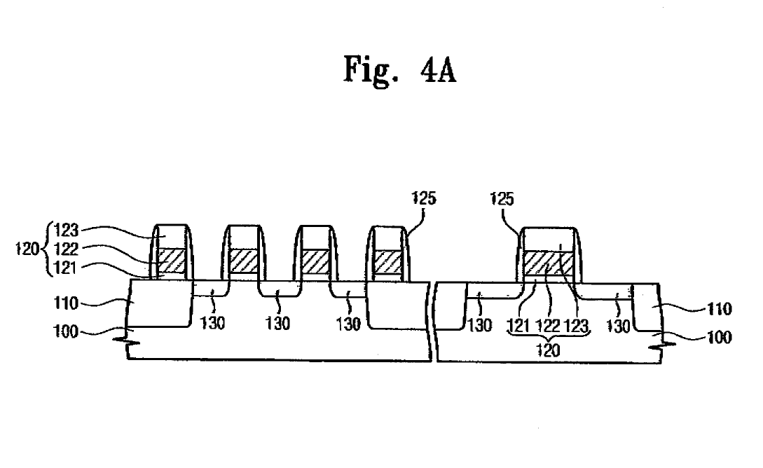

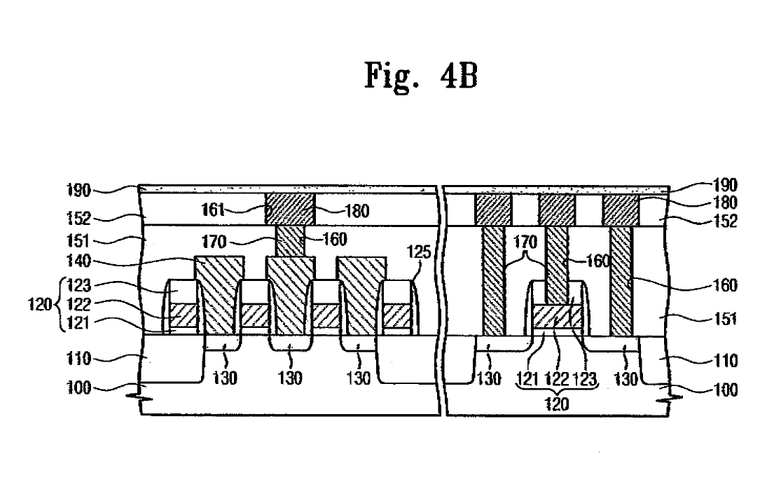

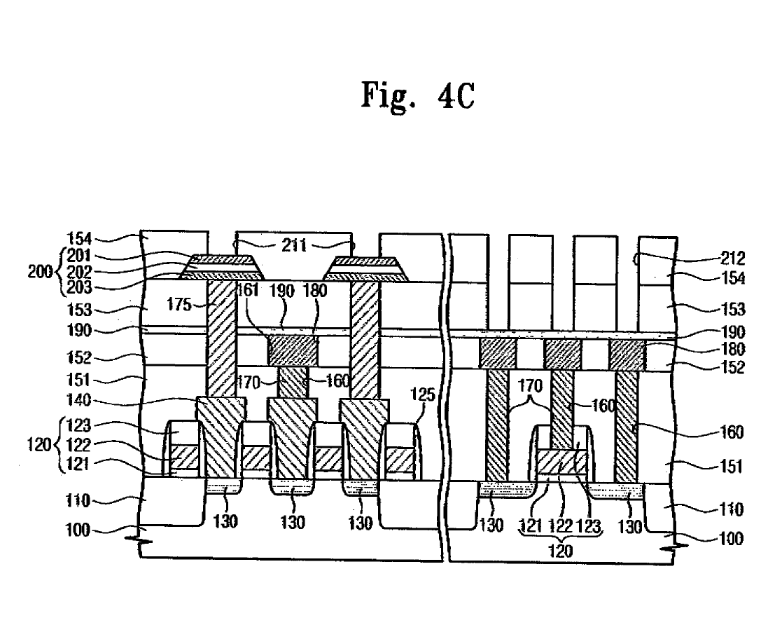

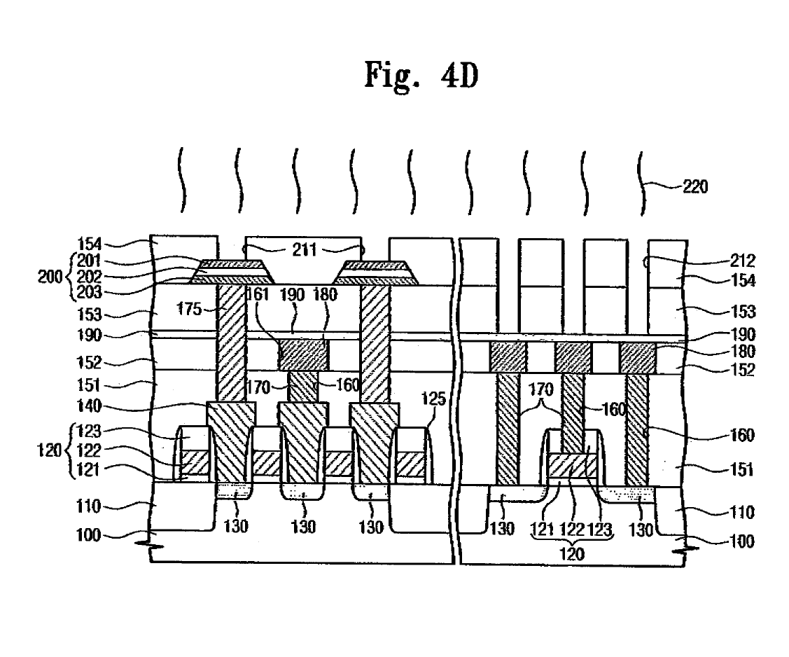

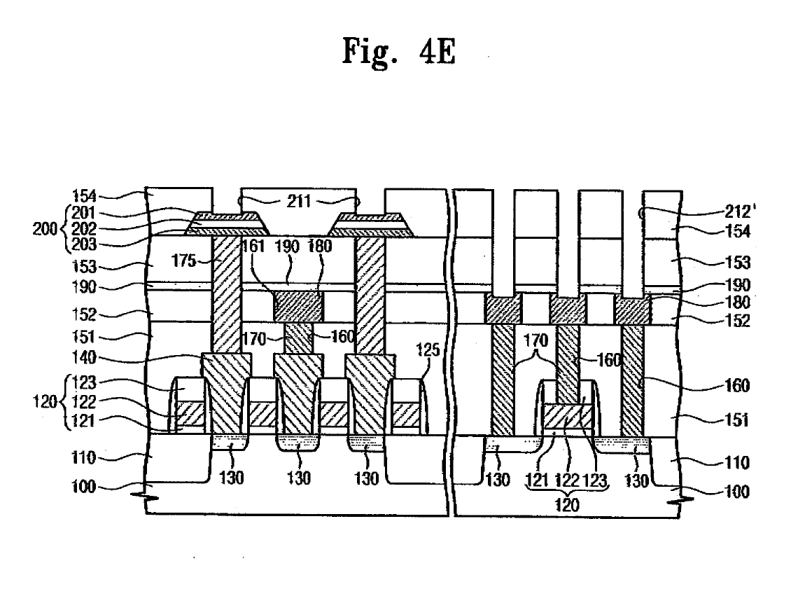

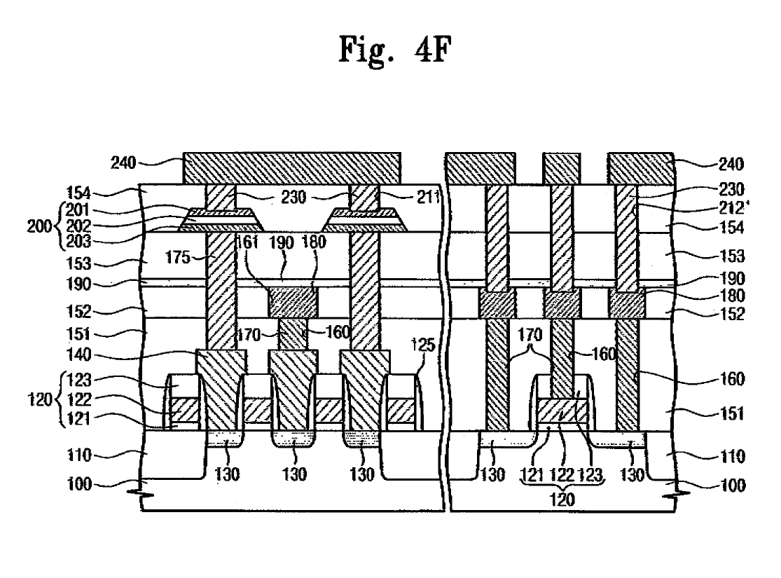

A method of forming an FeRAM according to an embodiment of the present invention will be described below with reference to FIG. 3 and FIGS. 4A through 4F.

Referring to FIG. 3 and FIG. 4A, a device isolation pattern 110 is formed on a semiconductor substrate 100 to define active regions, including a first region and a second region. According to the present embodiment, the first region may be a cell array region, in which memory cells are arranged, and the second region may be a peripheral circuit region, in which peripheral transistors connected to the memory cells are arranged. The device isolation pattern may be formed by means of shallow trench isolation (STI), for example.

Gate patterns 120 are formed on the resultant structure, where the device isolation pattern 110 is formed, to cross over the active regions. The gate patterns 120 include a gate insulator 121 and a gate electrode 122, which are stacked in the order listed. A capping pattern 123 may be disposed on the gate electrode 122. In the depicted embodiment, the gate insulator 121 and/or the gate electrode 122 of the first region may be different from those of the second region in thickness and/or material. In addition, gate spacers 125 may be formed at both sidewalls of the gate pattern 120, respectively.

Impurity regions 130 are formed at opposite active regions adjacent to the gate pattern 120 to be used as a source electrode and a drain electrode of a transistor, respectively. The impurity regions 130 may be formed by means of ion implantation using the gate pattern 120 or the gate spacer as an ion implanting mask. The impurity regions 130 have a different conductivity type from the active region. In this embodiment, the impurity regions 130 formed at the first region and the impurity regions 130 formed at the second region may be the same or different in conductivity type, impurity concentration and/or doping profile.

Referring to FIG. 3 and FIG. 4B, a first interlayer dielectric 151 is formed on the resultant structure where the impurity regions 130 are formed. The first interlayer dielectric 151 may be formed from silicon oxide, for example, and may include silicon nitride. The first interlayer dielectric 151 is patterned, forming bottom openings 160 to expose a top surface of each impurity region 130 and a top surface of the gate electrode 122. In the depicted embodiment, before forming the bottom openings 160, studs 140 may be formed to connect to the impurity regions 130. Since the studs 140 decrease the depth of the bottom opening 160 in the first region, an etching process for forming the bottom opening 160 may be performed stably.

Bottom plugs 170 are formed to fill the bottom openings 160. As a result, the bottom plugs 170 are electrically connected to the impurity regions 130 or the gate electrode 122. When a stud 140 is included, the stud 140 is interposed between the bottom plug 170 and the impurity region 130 to make an electrical connection.

A second interlayer dielectric 152 is formed on the resultant structure where the bottom plugs 170 are formed. The second interlayer dielectric 152 is formed to define a groove region 161 exposing the top surfaces of the bottom plugs 170. A conductive layer (not shown) may be formed on the second interlayer dielectric 152. The conductive layer is planarized down to the top surface of the second interlayer dielectric 152. As a result, conductive patterns 180 filling the groove region 161 are formed to be electrically connected to the bottom plugs 170 (S50). For example, the conductive patterns 180 may be formed by means of a damascene process.

The conductive patterns 180 may be used as an interconnection, which electrically connects the bottom plugs 170 with each other or a pad for connection between the bottom plug 170 and top plugs (e.g., top plugs 230 of FIG. 4F), formed in a subsequent process. The conductive pattern 180 may be formed from low-price materials, such as tungsten, aluminum and copper. When the conductive pattern 180 is made of a low-price material, the production cost may lower than when the conductive pattern 180 is made of a noble metal.

An etch-stop layer 190 is formed on the entire surface of the resultant structure where the conductive pattern 180 is formed (S52). The etch-stop layer 190 is made of an insulating material capable of preventing diffusion and penetration of oxygen and has an etch selectivity with respect to silicon oxide. In this embodiment, the etch-stop layer 190 may be formed from at least one of low pressure chemical vapor deposition silicon nitride (LP-CVD SiN), plasma enhanced chemical vapor deposition silicon nitride (PE-CVD SiN), chemical vapor deposition aluminum oxide (CVD Al₂O₃) and atomic layer deposition aluminum oxide (ALD Al₂O₃). More generally, the etch-stop layer 190 may be formed from aluminum oxide and silicon nitride, stacked in the order listed, or solely from silicon nitride or aluminum oxide.

Referring to FIG. 3 and FIG. 4C, a third interlayer dielectric 153 is formed on the resultant structure, including the etch-stop layer 190. A cell plug 175 is formed to connect to the stud 140 through the third interlayer dielectric 153. A ferroelectric capacitor 200 is formed on the third interlayer dielectric 153 (S54). The ferroelectric capacitor 200 is located in the first region to be connected to the cell plug 175. The ferroelectric capacitor 200 may include a bottom electrode 203, a ferroelectric layer 202 and a top electrode 201, which are stacked in the order listed. A fourth interlayer dielectric 154 is formed on the resultant structure, on which the ferroelectric capacitor 200 is formed (S56). According to the present embodiment, each of the third and fourth interlayer dielectrics 153 and 154 may be made of silicon oxide, for example.

The fourth and third interlayer dielectrics 154 and 153 are patterned to form a first opening 211, exposing the top surface of the ferroelectric capacitor 200 in the first region, and a second opening 212, exposing the top surface of the etch-stop layer 190 in the second region (S58). According to the present embodiment, the first and second openings 211 and 212 are simultaneously formed through one process step. For this reason, the formation of the first and second openings 211 and 212 may be performed using an etch recipe capable of selectively etching the fourth and third interlayer dielectrics 154 and 153, and minimizing the etching of the top electrode 201 and the etch-stop layer 190. Owing to the use of the etch recipe, the top surfaces of the conductive patterns 180 are not exposed by the second openings 212, as illustrated in FIG. 4C.

Referring to FIG. 3 and FIG. 4D, the resultant structure in which the first and second openings 211 and 212 are formed is annealed 220 in an oxygen-containing ambient (S60). Since charges accumulated at the top electrode 201 of the ferroelectric capacitor 200 are removed by the oxygen annealing step, as previously described in the background section, degradation of the remnant polarization characteristic of FeRAM can be prevented by means of the oxygen annealing.

In this embodiment, the etch-stop layer 190, which is formed from a material capable of preventing of oxygen diffusion, is formed on the entire surface of the semiconductor substrate 100. Thus, the etch-stop layer 190 serves to prohibit oxygen atoms from penetrating into the conductive pattern 180, and therefore preventing oxidation of the conductive pattern 180.

Referring to FIG. 3 and FIG. 4E, the portion of the etch-stop layer exposed through the second opening 212 is selectively etched, forming an extended second opening 212′ to expose the top surface of the conductive pattern 180 (S62). An etch recipe used in this etching step selectively etches the etch-stop layer 190, while minimizing the etching of the fourth interlayer dielectric 154 and the top electrode 201. The selective etching may be a wet etching or a dry etching. In the depicted embodiment, the selective etching is a plasma dry etching, for example in the case where the selective etching is the plasma dry etching, the top surfaces of the conductive pattern 180 and the top electrode 201 may be recessed to a predetermined depth.

Since the fourth interlayer dielectric 154 including the first and second openings 211 and 212 is used as an etch mask in the selective etching, a pattern process performed to expose the top electrode 201 is not needed. That is, because the first and second openings 211 and 212 are simultaneously formed, the process of forming an FeRAM is simplified over conventional methods.

Referring to FIG. 3 and FIG. 4F, top plugs 230 are formed to fill each first opening 211 and each extended second opening 212′ (S64). Top interconnections 240 are formed to be connected to the top plugs 230.

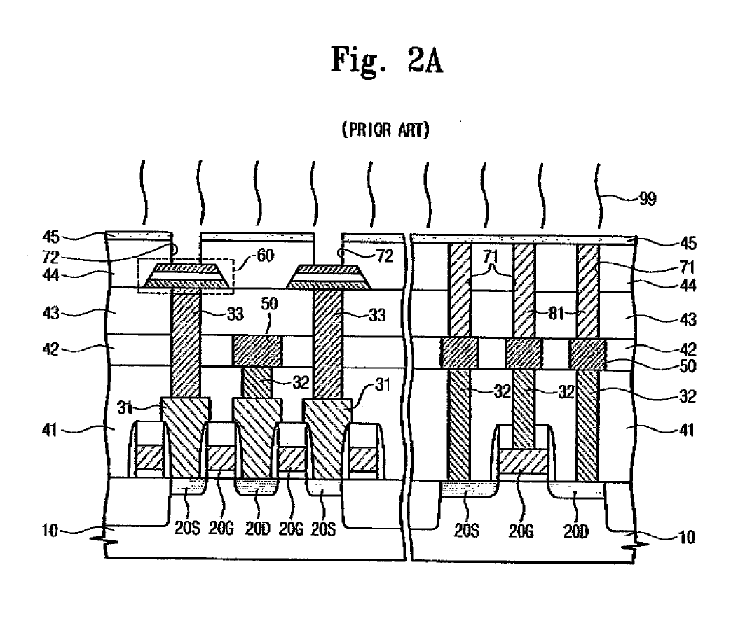

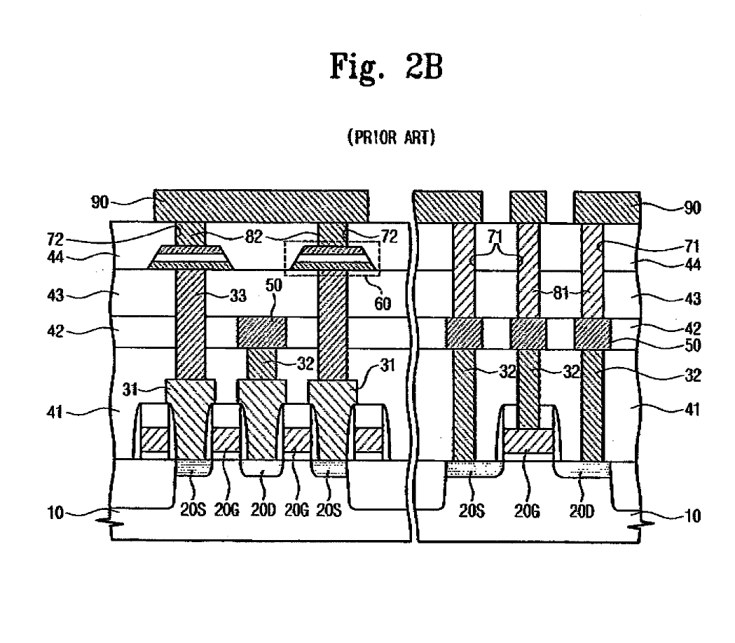

The top plugs 230 may be classified into a first top plug disposed in the first region and a second top plug disposed in the second region. In comparison, in the conventional art described with reference to FIG. 2B, the first and second top plugs 81 and 82 are formed through different process steps and of different materials, making the fabricating process more complex. Meanwhile, because the first and second top plugs 230 according to the present embodiment are simultaneously formed through one process, the first and second top plugs 230 are formed from the same material, which is simplified over conventional methods.

In addition, according to the conventional art, the first top plug 81 and the top interconnection 90 are simultaneously formed. Hence, they are made of the same material, i.e., aluminum. However, because a filling property of the aluminum is worse than that of tungsten, an aspect ratio of an opening (e.g. second opening 72 of FIG. 2A) formed to expose the top electrode must be maintained below a predetermined value. Thus, the level of integration of conventional FeRAMs has been limited. In comparison, according to the depicted embodiment of the present invention, the first and second top plugs are made of tungsten, which has a favorable filling property and which can be formed without additional process steps. Hence, the FeRAM according to the present embodiment can be fabricated to have a higher level of integration.

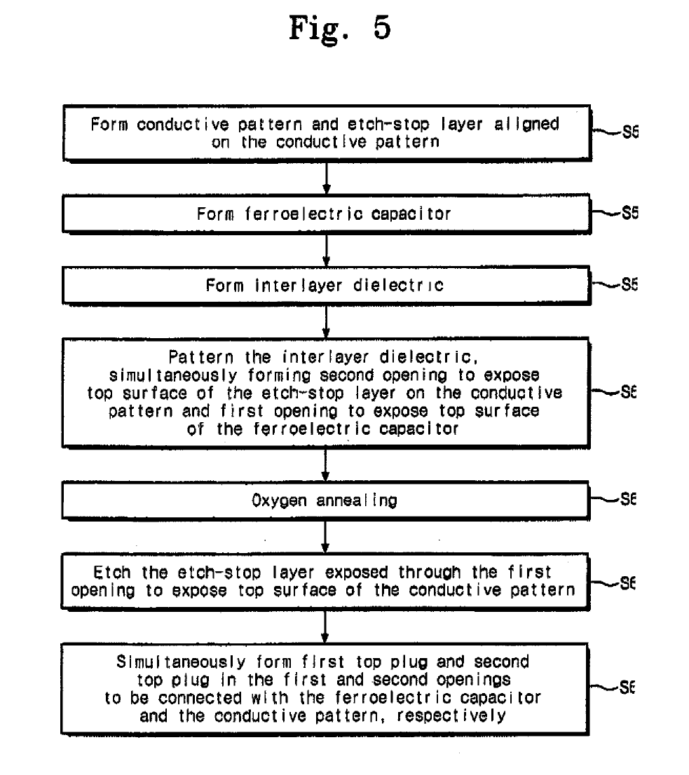

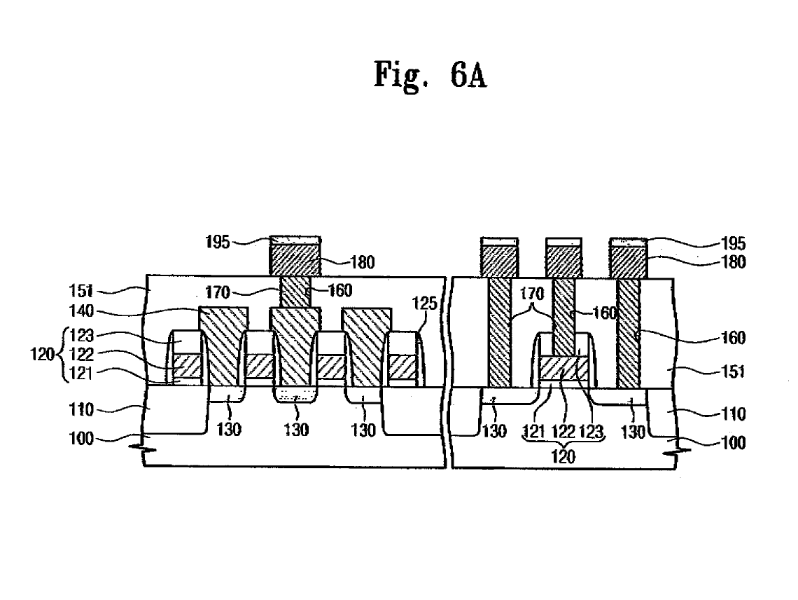

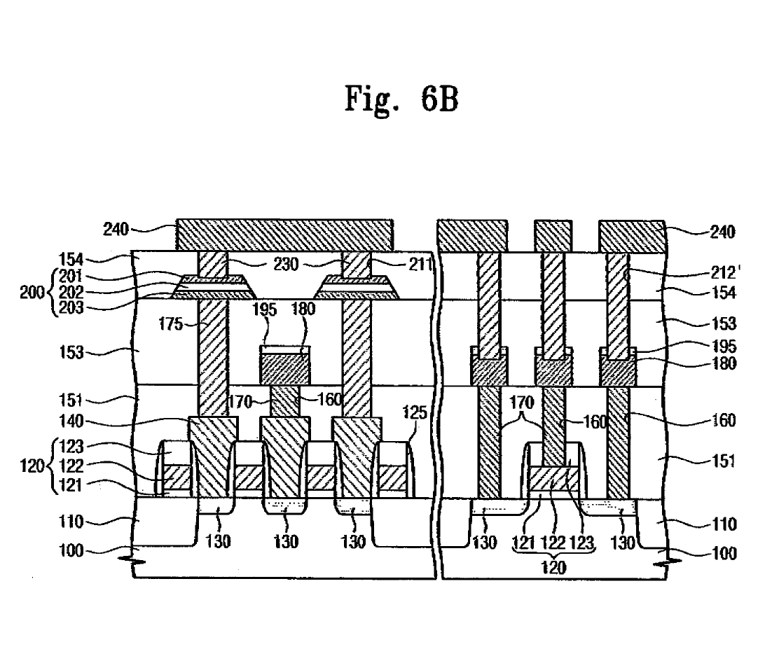

A method of forming an FeRAM according to another embodiment of the present invention will be described below with reference to FIG. 5 and FIGS. 6A and 6B. This embodiment is substantially the same as the embodiment described with reference to FIGS. 4A through 4F, except that the etch-stop layer is patterned during an etching process performed to form the conductive pattern. Accordingly, description of duplicate features will not be repeated for brevity of explanation.

Referring to FIG. 5 and FIG. 6A, a conductive layer (not shown) and a capping layer (not shown) are sequentially formed on the resultant structure where the first interlayer dielectric 151 is formed. The conductive layer is electrically connected to the bottom plug 170 and may be formed from a low-price material, such as tungsten, aluminum and/or copper, as described with reference to FIG. 4B. The capping layer is made of an insulating material that is capable of preventing diffusion and penetration of oxygen, and has an etch selectivity with respect to silicon oxide, for example. In this embodiment, the capping layer may be made of at least one of low pressure chemical vapor deposition silicon nitride (LP-CVD SiN), plasma enhanced chemical vapor deposition silicon nitride (PE-CVD SiN), chemical vapor deposition aluminum oxide (CVD Al₂O₃) and atomic layer deposition aluminum oxide (ALD Al₂O₃). More generally, the capping layer may be formed from aluminum oxide and silicon nitride that are stacked in the order listed, or solely from silicon nitride or aluminum oxide. Also the capping layer may be used as an etch mask for forming a subsequent conductive pattern 180. In this case, the capping layer may further include silicon oxide or silicon oxynitride, as well as the silicon nitride and the aluminum oxide.

The capping layer and the conductive layer are patterned to form a conductive pattern 180 connected to the bottom plugs 170 and an etch-stop layer 195 disposed on the conductive pattern 180 (S50′). The etch-stop layer 195 is obtained by patterning the capping layer, and is automatically aligned with the conductive pattern 180. The etch-stop layer 195 thus is not formed to cover the entire surface of the semiconductor substrate 100, which is different from the above-described embodiment.

Referring to FIG. 5 and FIG. 6B, steps for forming a third interlayer dielectric 153, which covers the conductive pattern 180 and the etch-stop layer 195, through forming the top interconnection 240 may be the same as the steps previously described with reference to FIGS. 4C through 4F.

In other words, in the present embodiment, the second opening 212 is formed to expose the top surface of the etch-stop layer 195, as opposed to the top surface of the conductive pattern 180. Further, formation of the second opening 212 is performed simultaneously with formation of a first opening 211 to expose the top electrode 201 of the ferroelectric capacitor 200. The oxygen annealing 220 is performed while the etch-stop layer 195 covers the entire top surface of the conductive pattern 180, in order to prevent oxidation of the top surface of the conductive pattern 180. After performing the oxygen annealing 220, the etch-stop layer 195 is re-patterned to form an extended second opening 212′, exposing the top surface of the conductive pattern 180.

According to embodiments of the present invention, an etch-stop layer is formed to cover at least the top surface of a conductive pattern. The etch-stop layer makes it possible to simultaneously form a first opening, exposing a top electrode of a ferroelectric capacitor, and a second opening, exposing a conductive pattern in a peripheral circuit region. Thus, the number of process steps for forming an FeRAM decreases, thus reducing the FeRAM fabricating cost. The etch-stop layer is made of an insulating material that is capable of preventing the diffusion of oxygen to prevent oxidation of the conductive pattern during the oxygen annealing process performed after formation of the first and second openings. As a result, the number of poor-quality products caused by contact resistance decreases and the number of process steps decreases, reducing fabricating costs.

While the present invention has been described with reference to illustrative embodiments, it will be apparent to those skilled in the art that various changes and modifications may be made without departing from the spirit and scope of the present invention. Therefore, it should be understood that the above embodiments are not limiting, but illustrative.

What is claimed is:

1. A method of fabricating a ferroelectric random access memory, the method comprising:
sequentially forming a conductive pattern, an etch-stop layer, a ferroelectric capacitor, and an interlayer dielectric on a semiconductor substrate, the semiconductor substrate comprising a first region and a second region, the ferroelectric capacitor being formed on the first region and the conductive pattern being formed on the second region;
patterning the interlayer dielectric to simultaneously form a first opening to expose a top surface of the ferroelectric capacitor and a second opening to expose a top surface of the etch-stop layer;
annealing the patterned interlayer dielectric, in which the first and second openings are formed, in ambient oxygen;
etching the etch-stop layer exposed through the second opening to expose a top surface of the conductive pattern; and
simultaneously forming a first top plug and a second top plug to be connected to the ferroelectric capacitor and the conductive pattern through the first and second openings, respectively.

2. The method as recited in claim 1, wherein the etch-stop layer comprises an insulating material to prevent oxygen atoms from penetrating.

3. The method as recited in claim 2, wherein the etch-stop layer is formed using at least one selected from a group consisting of low pressure chemical vapor deposition silicon nitride (LP-CVD SiN), plasma enhanced chemical vapor deposition silicon nitride (PE-CVD SiN), chemical vapor deposition aluminum oxide (CVD Al₂O₃), and atomic layer deposition aluminum oxide (ALD Al₂O₃).

4. The method as recited in claim 1, wherein the etch-stop layer is formed to substantially cover an entire surface of the semiconductor substrate during the annealing, preventing oxygen atoms from coming in contact with the conductive pattern.

5. The method as recited in claim 4, wherein forming the conductive pattern and the etch-stop layer comprises:
forming a bottom interlayer dielectric on the semiconductor substrate, the bottom interlayer dielectric comprising a groove region for defining the conductive pattern;
forming a conductive layer on the bottom interlayer dielectric to fill the groove region;
planarizing the conductive layer to a top surface of the bottom interlayer dielectric to form the conductive pattern disposed in the groove region; and
forming the etch-stop layer on a surface including the conductive pattern.

6. The method as recited in claim 1, wherein the etch-stop layer is formed to cover only a top surface of the conductive pattern during the annealing, preventing oxygen atoms from coming in contact with the conductive pattern.

7. The method as recited in claim 1, wherein forming the conductive pattern and the etch-stop layer comprises:
sequentially forming a conductive layer and a capping layer on the semiconductor substrate; and
patterning the capping layer and the conductive layer to form the conductive pattern and the etch-stop layer, which is sequentially stacked on the conductive pattern,
wherein the etch-stop layer is self-aligned with the conductive pattern.

8. The method as recited in claim 1, wherein the conductive pattern comprises at least one of tungsten, aluminum and copper; and
wherein each of the first top plug and the second top plug comprises at least one of tungsten, aluminum and copper, and the first top plug and the second top plug comprise the same material.

9. A ferroelectric random access memory comprising:
a conductive pattern and a ferroelectric capacitor located on a first region and a second region of a semiconductor substrate, respectively;
an interlayer dielectric located on the conductive pattern and the ferroelectric capacitors the interlayer dielectric defining a first opening and a second opening formed in the first region and the second region, respectively;
an insulative etch-stop layer located between the conductive pattern and the interlayer dielectric; and
a first top plug and a second top plug located in the first opening and the second opening, respectively,
wherein the insulative etch-stop layer comprises a material having an etch selectivity with respect to the interlayer dielectric and having an oxygen-blocking property to prevent oxygen from penetrating into the conductive pattern; and
wherein the first top plug is connected to a top surface of the ferroelectric capacitor and the second top plug is connected to a top surface of the conductive pattern through the etch-stop layer.

10. The ferroelectric random access memory as recited in claim 9, wherein the first and second top plugs comprise substantially the same material and are formed concurrently.

11. The ferroelectric random access memory as recited in claim 9, wherein the conductive pattern comprises at least one of tungsten, aluminum and copper; and
wherein each of the first and second top plugs comprises at least one of tungsten, aluminum and copper.

12. The ferroelectric random access memory as recited in claim 9, wherein the insulative etch-stop layer comprises at least one selected from a group consisting of low pressure chemical vapor deposition silicon nitride (LP-CVD SiN), plasma enhanced chemical vapor deposition silicon nitride (PE-CVD SiN), chemical vapor deposition aluminum oxide (CVD Al₂O₃), and atomic layer deposition aluminum oxide (ALD Al₂O₃).

13. The ferroelectric random access memory as recited in claim 9, wherein the insulative etch-stop layer is self-aligned with the conductive pattern.

14. The ferroelectric random access memory as recited in claim 9, wherein the insulative etch-stop layer extends across substantially an entire surface of the semiconductor substrate, except where the second top plug is formed.
